(19) United States
(12) Patent Application Publication
(10) Pub. No.: US 2006/0005110 A1
(43) Pub. Date: Jan. 5, 2006

(54) Data processing apparatus and method

(75) Inventors: Takahiro Nango, Ome-shi (JP); Yukiyasu Tatsuzawa, Yokohama-shi (JP)

Correspondence Address: PILLSBURY WINTHROP SHAW PITTMAN, LLP, P.O. BOX 10500, MCLEAN, VA, 22102, US

(73) Assignee: KABUSHIKI KAISHA TOSHIBA, Tokyo (JP)

(21) Appl. No.: 11/168,305

(22) Filed: Jun. 29, 2005

(30) Foreign Application Priority Data
Jun. 30, 2004 (JP) 2004-194937

(51) Int. Cl. H03M 13/00

(52) U.S. Cl. 714/785

(57) ABSTRACT

A data processing apparatus may include a memory unit which stores information including sync frame data, a preceding calculation system circuit which makes a syndrome calculation from the information including sync frame data, a retry calculation system circuit which makes a syndrome calculation from information stored in the memory unit, a buffer group which stores a calculation result of the preceding calculation system circuit or that of the retry calculation system circuit, and a correction execution process system circuit which executes error correction for the information including sync frame data according to the calculation result stored in the buffer group.

### CROSS-REFERENCE TO RELATED APPLICATIONS

This application is based upon and claims the benefit of priority from prior Japanese Patent Application No. 2004-194937, filed Jun. 30, 2004, the entire contents of which are incorporated herein by reference.

### BACKGROUND OF THE INVENTION

1. Field of the Invention

The present invention relates to a data processing apparatus and method, which perform a data process including error correction to data read out from an information medium such as an optical disc or the like on the basis the DVD (Digital Versatile Disc) standard and, more particularly, improvement of a data processing apparatus and method, which perform a syndrome calculation.

2. Description of the Related Art

In recent years, DVDs that record and/or play back digital data (a DVD-ROM/R/RW/RAM; or an HD-DVD streamer which digitally records/plays back DVD video for AV, DVD-VR compatible to recording/playback, and MPEG-TS in the near future) have prevailed remarkably. On an optical disc based on the DVD standard, sector data generated based on error correction code (ECC for short) blocks are recorded.

Each error correction code block is made up of a block of information symbols arranged in the column and row directions, inner-code PI parity which is appended to information symbols in the row direction contained in the information symbol block, and outer-code PO parity which is appended to both information symbols in the column direction contained in the information symbol block and the inner-code PI parity. An error correction code in the PO direction has a code length of 208 bytes, an information length of 192 bytes, and a minimum distance of 17. An error correction code in the PI direction has a code length of 182 bytes, an information length of 172 bytes, and a minimum distance of 11.

Sector data generated from such error correction code blocks includes an error correction code, and can undergo error correction using this error correction code (Jpn. Pat. Appln. KOKAI Publication No. 2002-74861).

Also, a technique associated with an error correction process that supports multiple-speed playback is available. That is, a technique for calculating a syndrome for data with a code length of 182 bytes in the PI direction included in playback information parallel to a process for temporarily storing the playback information read out from a DVD on a buffer memory is available (Jpn. Pat. Appln. KOKAI Publication No. 2001-67822).

However, the method of calculating a syndrome parallel to the data write process on the buffer memory (Jpn. Pat. Appln. KOKAI Publication No. 2001-67822) can offer an advantage in coping with high multiple-speed playback, but poses a problem of a measure against sync abnormality in a DVD.

For example, in a DVD, upon conversion of recording data into sector data, data with a code length of 182 bytes in the PI direction form two sync frames. One sync frame includes a sync code (2 bytes) and 91 bytes of the code length of 182 bytes in the PI direction. A DVD system executes a synchronization process for respective sync frames. A sync system suffers abnormality for various reasons such as the state of a servo system of the DVD system, scratches, fingerprints, dust, and the like, and at least one sync frame may be lost or duplicated, or the arrival order of frames may be reversed.

Such trouble of Sync frames often disturbs a calculation of an effective syndrome of a data sequence (the code length of 182 bytes in the PI direction). Even if 91 bytes of one sync frame are correct data, all 182 bytes of both the sync frames may be consequently determined as error data. Such burst error results in an error correction performance drop and causes correction errors.

Also, in a syndrome calculation circuit which performs a syndrome calculation of an error correction code made up of a plurality of sync frames parallel to a write process to a buffer memory like in a DVD, if at least one sync frame is lost or arrives in a wrong order, the syndrome calculation of that data sequence cannot be effectively used, and the error correction performance drops consequently. As a measure against this problem, when an arithmetic circuit is designed to complete a syndrome calculation for each sync frame, a syndrome calculation is effectively realized even when frame loss has occurred (however, it is not a known technique). With this idea, when sync frame data duplication has occurred, second arrived data is ignored, and the process is done using first arrived data. However, with this method, when the first arrived data is wrong and the second arrived data is correct in many cases, uncorrectable cases occur.

### BRIEF SUMMARY OF THE INVENTION

A data processing apparatus according to an embodiment of the present invention includes a memory unit (17, 18) which stores information including sync frame data, a preceding calculation system circuit (140P) which performs a syndrome calculation from the information including sync frame data, a retry calculation system circuit (140R) which performs a syndrome calculation from information stored in the memory unit (17), a buffer group (150) which stores the calculation result of the preceding calculation system circuit (140P) or that of the retry calculation system circuit (140R), and a correction execution process system circuit (190) which executes error correction for the information including sync frame data on the basis of the calculation result stored in the buffer group.

According to the embodiment of the present invention, since the retry calculation system circuit (140P) is provided, when sync frame data is duplicated, second arrived data can be processed without being ignored, thus improving the correction efficiency.

### BRIEF DESCRIPTION OF THE SEVERAL VIEWS OF THE DRAWING

FIG. 1 shows an example of the data structure of an error correction code block;

FIG. 2 shows an example of the data structure of a data block with sync codes, which is recorded on an information storage medium such as a DVD or the like for respective predetermined recording units (sectors);

FIG. 3 is a schematic block diagram showing the arrangement of a playback system (data processing apparatus or disc drive) according to an embodiment of the present invention;

FIG. 4 is a block diagram showing details of a PI syndrome calculation circuit and PI syndrome buffer memory;

FIGS. 5A to 5E are tables showing sequences of respective switches in the PI syndrome calculation circuit shown in FIG. 4;

FIG. 6 is a flowchart showing an example of the sequence of an error correction process;

FIG. 7 is a schematic block diagram showing the arrangement of a playback system (data processing apparatus or disc drive) according to another embodiment of the present invention;

FIG. 8 is a view showing the concept of data transfer in the system arrangement shown in FIG. 7;

FIG. 9 is a view for explaining a case wherein sync frame data arrive normally and a case wherein sync frame data arrive redundantly (sync abnormality) in the system arrangement shown in FIG. 7;

FIG. 10 is a flowchart showing a processing example in the system arrangement shown in FIG. 7;

FIG. 11 is a block diagram showing an example of details of an ECC decode system module (LSI or the like) in the system arrangement shown in FIG. 7; and

FIG. 12 is a diagram for explaining the concept of the operation of an ECC decode process in the system arrangement shown in FIG. 7.

### DETAILED DESCRIPTION OF THE INVENTION

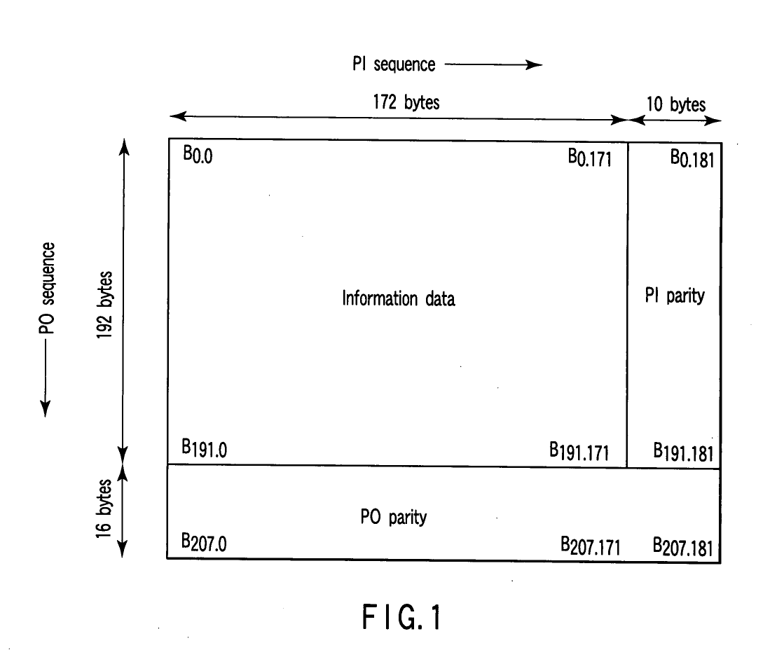

Embodiments of the present invention will be described hereinafter with reference to the accompanying drawings. FIG. 1 shows an example of the data structure of an error correction code block. As shown in FIG. 1, an error correction code block (ECC block) is made up of a block of information symbols (information data) arranged in the column direction (PO sequence) and row direction (PI sequence), inner-code PI parity which is appended to information symbols in the row direction contained in the information symbol block, and outer-code PO parity which is appended to both information symbols in the column direction contained in the information symbol block and the inner-code PI parity. In this example, an error correction code in the PO direction has a code length of 208 bytes, an information length of 192 bytes, and a minimum distance of 17. An error correction code in the PI direction has a code length of 182 bytes, an information length of 172 bytes, and a minimum distance of 11.

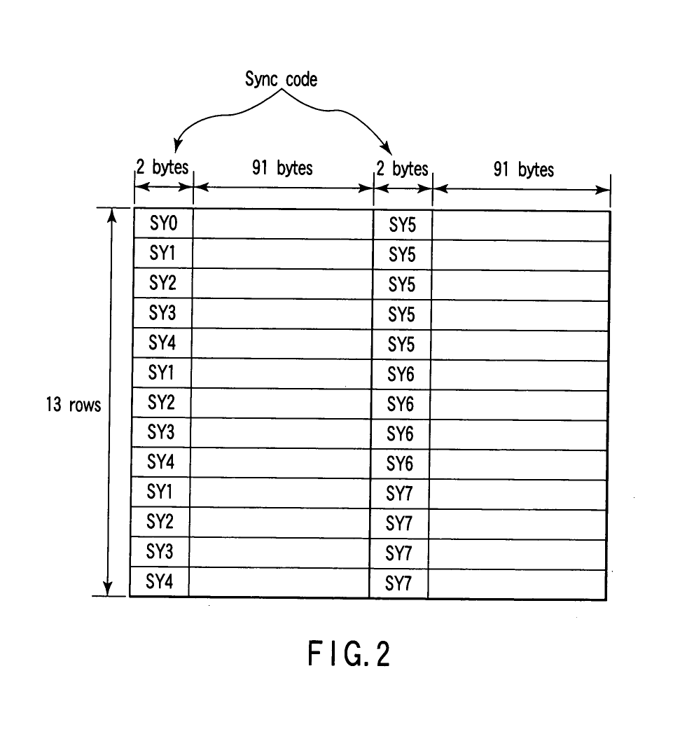

FIG. 2 shows an example of the data structure of a data block with sync code, which is recorded on an information storage medium such as a DVD or the like for respective predetermined recording units (sectors). As shown in FIG. 2, a data block with sync codes is generated by inserting sync codes in sector data at given intervals. Sector data is generated from some data of the error correction code block shown in FIG. 1. More specifically, a block of 192 rows formed by the information symbol (information data) block and PI parity is divided into 16 blocks. That is, one divided block is formed of 12 rows. One of 16 PO parity rows is added to one divided block formed of 12 rows to generate sector data of 13 rows. The total number of divided blocks is 16, and the total number of rows of PO parity is also 16. Hence, by adding one row of PO parity to each divided block, 16 sector data are generated. One sector data has (12+1) rows and (172+10) bytes per row.

When sync codes are inserted in the sector data generated in this way at, e.g., 91-byte intervals, a data block with sync codes shown in FIG. 2 is generated. The data block with sync codes has 13 rows and 186 bytes per row, as shown in FIG. 2. One row of the data block with sync codes, i.e., a data sequence includes two sync frames (2+91+2+91 bytes). One sync frame (2+91 bytes) includes a sync code (2 bytes) and some data of the sector data. A modulated data sequence obtained by removing sync codes from one data sequence includes an error correction code, and error correction can be achieved using this modulated data sequence.

In the example of FIG. 2, one sync frame is formed by 2-byte sync code+91-byte data, and a physical sector is formed by such sync frames for 26 frames (13 rows×2).

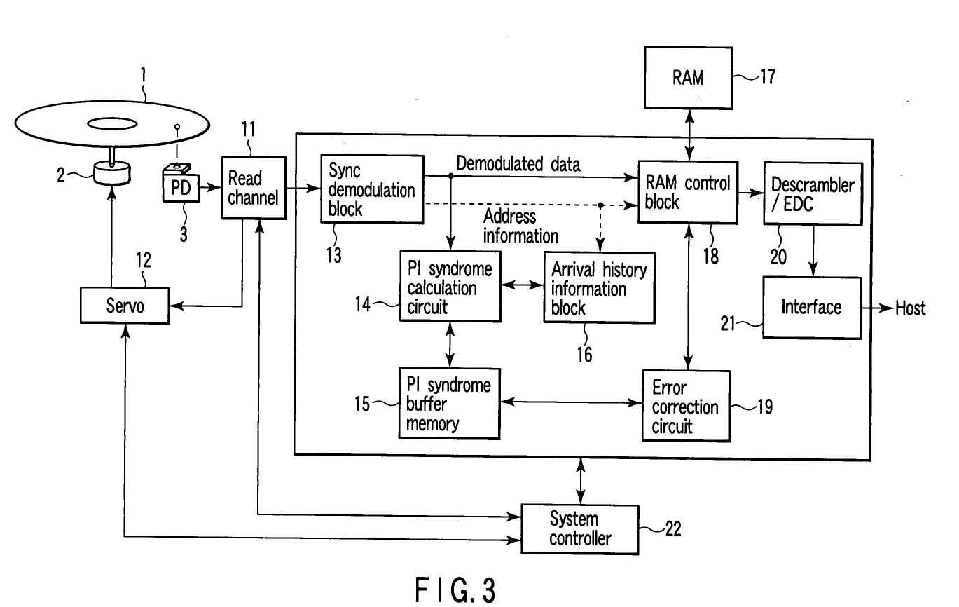

FIG. 3 is a schematic block diagram showing the arrangement of a DVD playback system (data processing apparatus or disc drive) according to an embodiment of the present invention. The flow of data in blocks will be described first. Optical disc (DVD-video disc or the like) 1 is rotated by spindle motor 2 which undergoes servo control. Data of a physical sector recorded on this disc 1 is detected by optical pickup 3, and the detected signal is sent to read channel 11 after it is amplified appropriately.

Data reproduced from disc by read channel 11 undergoes a signal process, and is then transmitted to sync demodulation block 13. Sync demodulation block 13 detects a sync code (see FIG. 2) included in the received data, and outputs modulated data (91 bytes) obtained by removing the sync code from this data. Furthermore, sync demodulation block 13 also outputs address information indicating the location of the output demodulated data in the error correction code block shown in FIG. 1.

RAM control block 18 stores the demodulated data output from sync demodulation block 13 in RAM 17. The demodulated data is also input to PI syndrome calculation circuit 14 parallel to the storage process in RAM 17. PI syndrome calculation circuit 14 calculates a syndrome so that the syndrome calculations can be realized by only 91 bytes of the demodulated data.

Arrival history information block 16 generates history information of a frame arrival state on the basis of the address information output from sync demodulation block 13. That is, arrival history information block 16 manages the read-out state of data from the disc for respective sync frames. PI syndrome calculation circuit 14 confirms history information generated by arrival history information block 16 prior to the syndrome calculations of 91 bytes, and always checks if frame loss, frame duplication, or the like has occurred.

Sync demodulation block 13 generates address information on the basis of ID information and sync codes included in data read out from disc 1 while effecting sync protection. If a sync operation does not suffer any abnormality, all pieces of address information sent to arrival history information block 16 assume serial values. Arrival history information block 16 may adopt a configuration for storing all pieces of address information, or a bitmap configuration with addresses of error correction code blocks.

Note that data recorded on DVD disc 1 have undergone an interleave process. Hence, demodulated data do not always arrive in the data arrangement order shown in FIG. 1. RAM control block 18 and PI syndrome calculation circuit 14 execute a storage process in RAM 17 and syndrome calculations while applying a deinterleave process on the basis of the address information. If no sync error (sync abnormality) is found, all data in an error correction code block arrive without any loss or duplication, and are stored in RAM 17. Also, PI syndrome calculations are executed after all data sequences are obtained. The PI syndrome calculation results are stored in PI syndrome buffer memory 15.

Error correction circuit 19 executes an error correction process using the PI syndrome calculation results. For example, when a correction process is executed from a PI sequence, an error pattern and error location are calculated using the PI syndrome calculation results to correct an information error in RAM 17. At this time, if all the PI syndrome calculation results are zero, no error is determined, and an error correction process is skipped.

On the other hand, when a correction process is executed from a PO sequence with a larger code length, a data sequence in the PO direction is read out from RAM 17, and a PO syndrome calculation circuit included in error correction circuit 19 executes syndrome calculations. After that, an error pattern and error location are calculated to correct an information error in RAM 17. In this case, loss correction can be executed by exploiting address information of a data sequence with “non-zero” PI syndrome calculation results, and the correction performance can be improved compared to normal correction.

After all correction processes are completed, and all information errors have been removed from the data in RAM 17, descrambler/EDC block 20 executes a final error check process via RAM control block 18, and data is transmitted to a host via interface 21.

A method of realizing syndrome calculations using data of only 91 bytes will be explained in detail below. In a coding theory used in an error correction process, input data I₀ to I₁₈₁ of a PI sequence are handled as input information equation I(x) given by:
I(x)=I₀x¹⁸¹+I₁x¹⁸⁰+. . . I₁₈₀x+I₁₈₁

The syndrome values of the PI sequence are calculated by substituting α⁰ to α⁹ as the roots of the Galois field in this input information equation I(x) and are given by:
S₀=I(á⁰)=I₀+I₁+. . . +I₁₈₀+I₁₈₁
S₁=I(á¹)=I₀á¹⁸¹+I₁á¹⁸⁰+. . . +I₁₈₀á+I₁₈₁
S₉=I(á⁹)=I₀á^{9×181}+I₁á^{9×180}+. . . +I₁₈₀á⁹+I₁₈₁)

If all these syndrome values S₀ to S₉ are zero, they indicate that reproduction data is free from any errors. However, in order to effect syndrome calculation equations, data of 182 bytes are required.

On the other hand, the above equations of S₀ to S₉ can be rewritten as:

$$\begin{matrix}{S}_{0} = ( {I}_{0} + {I}_{1} + … + {I}_{89} + {I}_{90} ) + ( {I}_{91} + {I}_{92} + … + {I}_{180} + {I}_{181} ) \\ {S}_{1} = ( {I}_{0} {á}^{90} + {I}_{1} {á}^{89} + … + {I}_{89} á + {I}_{90} ) {á}^{91} + \\ ( {I}_{91} {á}^{90} + {I}_{92} {á}^{89} + … + {I}_{180} á + {I}_{181} ) \end{matrix}$$

$$⋮$$

$$\begin{matrix}{S}_{9} = ( {I}_{0} {á}^{9 \times 90} + {I}_{1} {á}^{9 \times 89} + … + {I}_{89} {á}^{9} + {I}_{90} ) {á}^{9 \times 91} + \\ ( {I}_{91} {á}^{9 \times 90} + {I}_{92} {á}^{9 \times 89} + … + {I}_{180} {á}^{9} + {I}_{181} ) \end{matrix}$$

A formula in the former parentheses of each syndrome calculation equation represents the syndrome calculation result of the first 91 bytes of the PI data sequence. Also, a formula in the latter parentheses represents the syndrome calculation result of the second 91 bytes. That is, in case of the code length of 182 bytes, when the syndrome calculations are completed by the sync frame of the first 91 bytes, the syndrome calculation result of 91 bytes can be multiplied by α^{n×91} (where n is the syndrome degree). When the syndrome calculations are completed by the sync frame of the second 91 bytes, the syndrome calculation result of 91 bytes can be directly used.

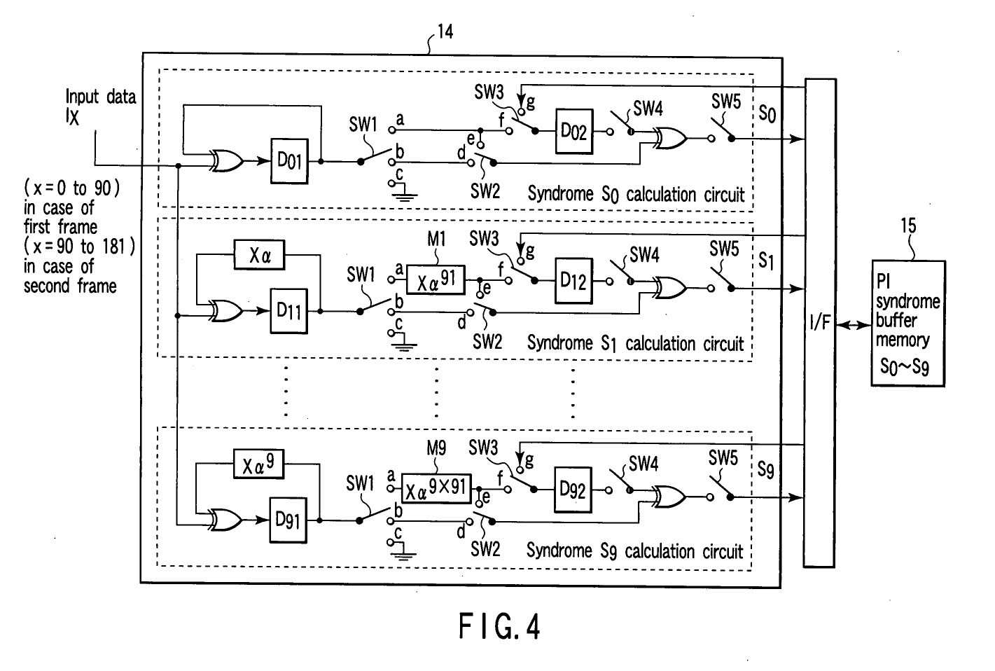

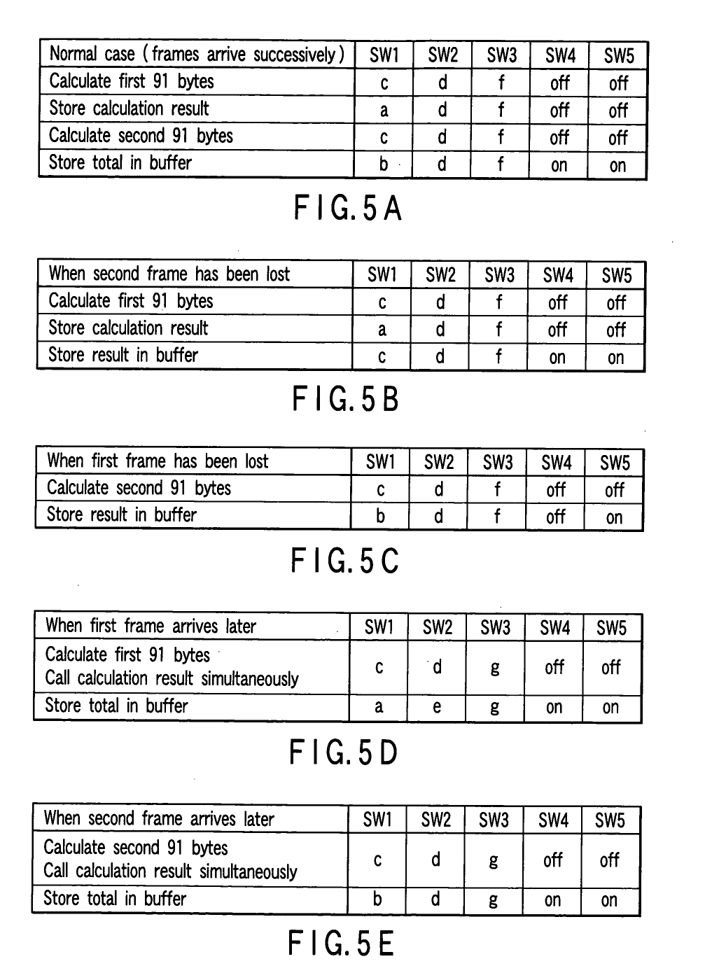

FIG. 4 is a block diagram showing details of PI syndrome calculation circuit 14 and PI syndrome buffer memory 15. FIGS. 5A to 5E show the sequences of respective switches in PI syndrome calculation circuit 14 shown in FIG. 4. The operations will be described below with reference to FIG. 4 and FIGS. 5A to 5E.

In PI syndrome calculation circuit 14 shown in FIG. 4, switches SW1 to SW5 operate in cooperation with each other in syndrome S₀ to S₉ calculation circuits. A normal operation free from any sync error will be examined first. While switches SW1 are flipped to the c side, 91 clocks are given to the circuit to execute syndrome calculations for only the first 91 bytes. The calculation results are latched by registers D₀₁ to D₉₁. Prior to the process of the second 91 bytes, switches SW1 are flipped to the a side, and switches SW3 are flipped to the f side. Multipliers M1 to M9 multiply the syndrome calculation results by α^{n×91}, and the products are latched by registers D₀₂ to D₉₂. During this process, switches SW5 are kept OFF.

Subsequently, syndrome calculations of the second 91 bytes are executed while switches SW1 are flipped to the c side as in the first 91 bytes, and the calculation results are latched by registers D₀₁ to D₉₁ again. Upon completion of the calculations of the second 91 bytes, switches SW1 are flipped to the b side in turn, switches SW2 are flipped to the d side, and switches SW4 are turned on, thus completing the EXORs of the syndrome calculation results of the first 91 bytes and the second 91 bytes. After that, switches SW5 are turned on, thus storing the syndrome calculation results of the PI data sequence with a code length of 182 bytes in PI syndrome buffer 15 (see FIG. 5A).

A method of coping with a case wherein frame loss has occurred will be explained below. A case will be exemplified below wherein the second 91 bytes have been lost. Such case is detected when the address of the sync frame of the next 91 bytes does not match that of the sync frame of the second 91 bytes while the syndrome calculation results of the first 91 bytes are stored in registers D₀₂ to D₉₂. In this case, the second frame loss is determined, and the calculation results in the registers are stored in PI syndrome buffer 15 as the syndrome calculation results of the PI data sequence of a code length of 182 bytes by flipping switches SW1 to the c side, and turning on switches SW4 and SW5 (see FIG. 5B).

On the other hand, the loss of the first 91 bytes is detected when an input address indicates that of second 91 bytes upon inputting the first 91 bytes in the normal operation. In such case, syndrome calculations for 91 bytes are made while flipping switches SW1 to the c side, and results are latched by registers D₀₁ to D₉₁. Upon completion of the calculations, switches SW1 are flipped to the b side, switches SW2 are flipped to the d side, switches SW4 are turned off, and switches SW5 are turned on. Then, the calculation results in the registers are stored in PI syndrome buffer 15 as the syndrome calculation results of the PI data sequence of the code length of 182 bytes (see FIG. 5C).

These syndrome calculation results obtained when data loss has occurred are equivalent to those calculated by using apparent zero data for those lost 91 bytes.

A case will be exemplified wherein the arrival order of frames is reversed. Such frame reverse is detected when the calculation results are temporarily stored in PI syndrome buffer 15 upon detection of a frame loss, but the frame which is determined as the lost frame arrives anew. In such case, the syndrome calculation results stored in PI syndrome buffer 15 must be called back.

For example, when the sync frame of the first 91 bytes arrives anew, switches SW1 are flipped to the c side to execute syndrome calculations for the first 91 bytes as in normal operation, and the calculation results are latched by registers D₀₁ to D₉₁. Parallel to these calculations, switches SW3 are flipped to the g side to call the syndrome results for the second 91 bytes in PI syndrome buffer 15 to latch them by registers D₀₂ to D₉₂. Upon completion of the calculations of the first 91 bytes, switches SW1 are flipped to the a side, and switches SW2 are flipped to the e side. Then, multipliers M1 to M9 multiply the results by α^{n×91}. Also, switches SW4 are turned on to compute the EXORs of the products and the calculation results of the second 91 bytes in registers D₀₂ to D₉₂. After that, switches SW5 are turned on to write the EXORs as the syndrome calculation results of the PI data sequence of the code length of 182 bytes in PI syndrome buffer 15 again (see FIG. 5D).

Likewise, when the sync frame of the second 91 bytes arrives anew, switches SW1 are flipped to the c side to execute syndrome calculations for the second 91 bytes as in normal operation, and the calculation results are latched by registers D₀₁ to D₉₁. Parallel to these calculations, switches SW3 are flipped to the g side to call the syndrome results for the first 91 bytes in PI syndrome buffer 15 to latch them by registers D₀₂ to D₉₂. Upon completion of the calculations of the second 9.1 bytes, switches SW1 are flipped to the b side, switches SW2 are flipped to the d side, and switches SW4 are turned on. Then, the EXORs of the calculation results in registers D₀₁ to D₉₁ and the calculation results of the first 91 bytes in registers D₀₂ to D₉₂ are computed. After that, switches SW5 are turned on to write the EXORs as the syndrome calculation results of the PI data sequence of the code length of 182 bytes in PI syndrome buffer 15 again (see FIG. SE).

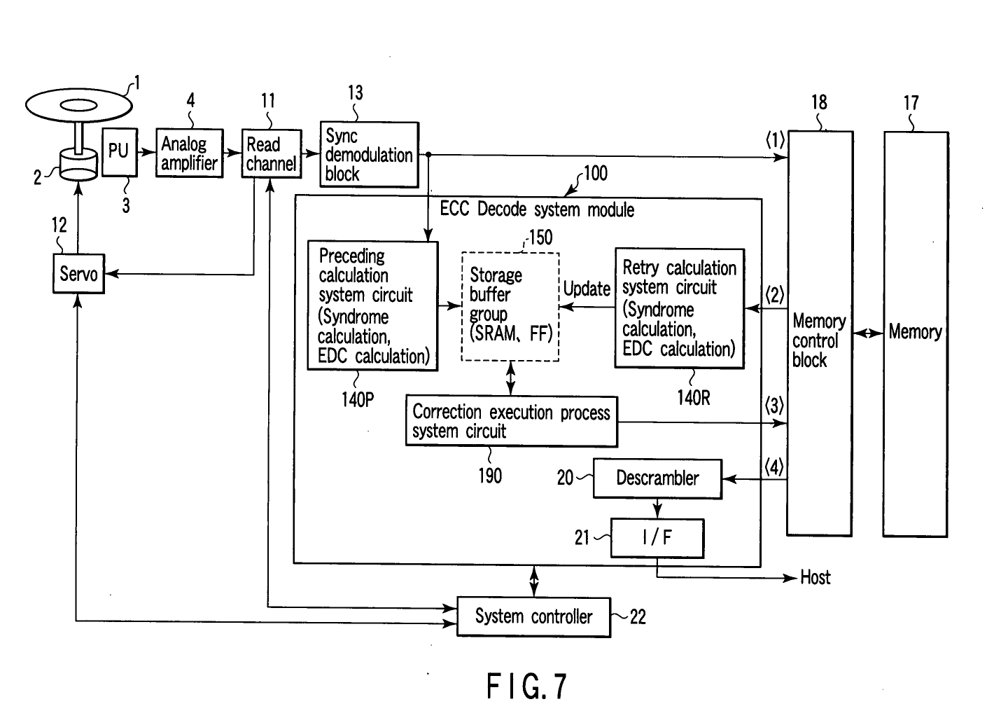

Next, a case will be explained below wherein frame duplication has occurred. Frame duplication is detected when a frame with an identical address arrives again. In this case (in one embodiment), PI syndrome calculation circuit 14 recognizes re-arrival of the identical address on the basis of the history information of arrival history information block 16, and skips the calculation process by ignoring the data of 91 bytes. Note that a case (another embodiment) wherein a syndrome calculation process is executed “when frame duplication has occurred” will be described later with reference to FIG. 7 and subsequent figures.

As described above, the circuit blocks with the arrangement shown in FIG. 4 can always realize syndrome calculations even when frame loss, frame reverse, and frame duplication have occurred.

When this PI syndrome calculation circuit 14 is used, matching with RAM 17 that stores playback information as main data must be taken account. In case of frame loss, PI syndrome calculation circuit 14 executes processes using apparent zero data. For this reason, when a DRAM or the like is used as RAM 17, data other than zero data may remain stored in RAM 17 as garbage data. For this reason, error correction circuit 19 pads data on the RAM at the lost address with zero data on the basis of the information of arrival history information block 16 prior to the error correction process. When both the first and second sync frames have been lost, data in PI syndrome buffer memory 15 must also be taken account. If extra data remain stored, they are similarly padded with zero data.

In such case, data appears to suffer no information error since syndromes are zero data. For this reason, when erasure correction of a PO sequence is used, the history information of arrival history information block 16 is used in addition to information indicating that syndromes are “not zero”, thus preventing correction errors due to this process.

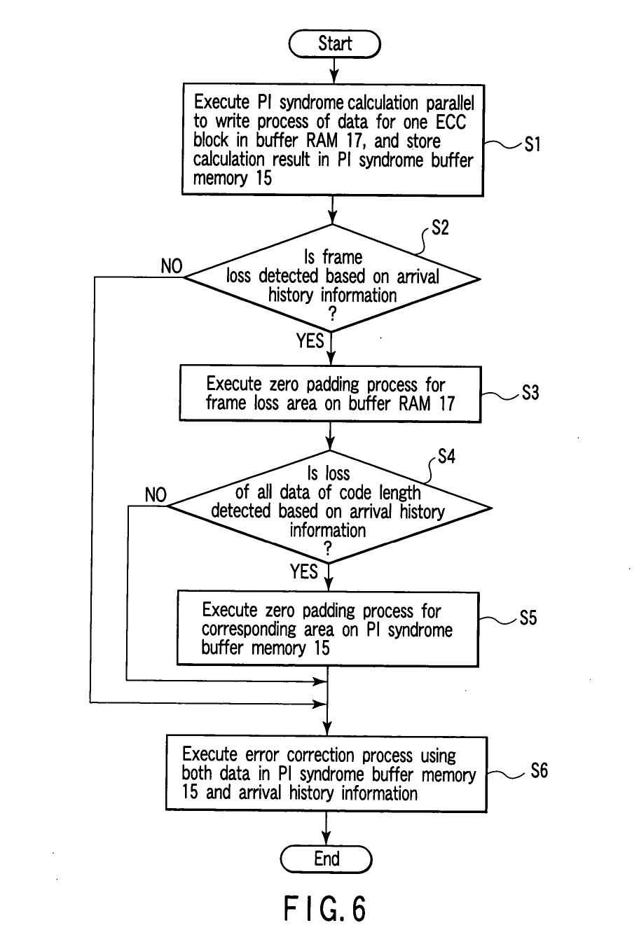

FIG. 6 is a flowchart showing an example of the sequence of the aforementioned error correction process. Data for one error correction block are written in RAM 17. Parallel to this write process, PI syndromes are calculated, and PI syndrome calculation results are stored in PI syndrome buffer memory 15 (step S1). If it is detected based on the arrival history information stored in arrival history information block 16 that frame loss has occurred (YES in step S2), an area on RAM 17 corresponding to the lost frame is padded with zero data (step S3).

If it is detected based on the arrival history information stored in arrival history information block 16 that all data of the code length have been lost (YES in step S4), extra data in PI syndrome buffer memory 15 are padded with zero data (step S5). An error correction process is executed using the data in PI syndrome buffer memory 15 and the arrival history information stored in arrival history information block 16 (step S6).

Characteristic features of the embodiment of the present invention described above will be summarized below.

(a) A data processing apparatus and method according to the present invention can complete syndrome calculations as an error correction code for each sync frame. For this reason, even when frame loss or the like has occurred due to abnormality in a sync system, syndrome calculation results parallel to the data write process on the buffer memory can be effectively used. Furthermore, diffusion of errors due to sync system abnormality can be prevented, and an error correction performance drop caused by such diffusion of errors can also be prevented.

(b) A data processing apparatus and method according to the present invention have an arrival history of sync frames. Hence, frame loss, frame duplication, reverse of the order of frames can always be recognized. Then, a syndrome calculation process that can cope with these problems of frame loss, frame duplication, reverse of the order of frames can be selectively executed.

(c) A data processing apparatus and method according to the present invention prevent correction errors using arrival history information of sync frames in addition to the syndrome calculation results, thus implementing more reliable error detection and error correction.

FIG. 7 is a schematic block diagram showing the arrangement of a playback system (data processing apparatus or disc drive) according to another embodiment of the present invention. The arrangement shown in FIG. 7 corresponds to the improved version of FIG. 3. In FIGS. 3 and 7, circuit blocks denoted by the same reference numerals have equivalent functions. Circuits 140P and 140R in FIG. 7 correspond to circuit 14 in FIG. 3 in terms of functions, and circuits 150 and 190 in FIG. 7 correspond to circuits 15 and 19 in FIG. 3 in terms of functions. Note that circuits 140P, 140R, 150, and 190 in FIG. 7 are provided with relatively higher functions (or other functions) than the corresponding circuits in FIG. 3.

More specifically, in the arrangement in FIG. 7, if no sync abnormality (sync frame duplication or the like) is found, preceding calculation system circuit 140P performs syndrome calculations and EDC (error detection code) calculations, and results are stored in storage buffer group 150. This operation corresponds to that of PI syndrome calculation circuit 14 and PI syndrome buffer memory 15 in the arrangement shown in FIG. 3. In the arrangement shown in FIG. 7, retry calculation system circuit 140R performs syndrome calculations and EDC (error detection code) calculations and the storage contents of storage buffer group 150 are updated by the calculation results (unlike in FIG. 3). The updated calculation results (those before update if no sync abnormality is found) are processed by correction execution process system circuit 190 (corresponding to error correction circuit 19 in FIG. 3).

More specifically, preceding calculation system circuit 140P in FIG. 7 recognizes data loss and reverse of sync abnormalities on the basis of arrival history information (see the description of block 16 in FIG. 3), and can calculate without contradiction. However, when sync frame data is duplicated, once the preceding syndrome calculations has been done, they cannot be redone since synchronization cannot be disturbed even when the same sync frame data arrives for the second time. As for data upon duplication, second arrived data commonly has higher reliability than first arrived data. That is, when first arrived data includes many errors, an uncorrectable state is more likely to occur if processes are made depending on the preceding syndrome calculation results. Hence, as a method of coping with a case wherein sync frame data has been duplicated, two modes are prepared. That is, a former sync frame which arrives first is used, or a latter sync frame which arrives second is used. This mode switching is notified by system controller 22 via sync demodulation block 13 using an ECCOVW signal (to be described later). The mode switching process based on this ECCOVW signal will be described later with reference to FIG. 10.

The system arrangement of FIG. 7 has the following modes:

(1) First-Come-First-Served Basis Mode (Preceding Calculation Results are Valid)

This mode requires higher multiple-speed playback. In order to give priority to the preceding syndrome results by preceding calculation system circuit 140P, if a sync frame is duplicated (if a sync abnormality has occurred), the former (first arrived sync frame) is prioritized, and the latter (second arrived sync frame) is ignored. On the memory (DRAM) 17 side as well, the former is prioritized and the latter is ignored to attain matching.

(2) Overwrite Permission Mode (Retry Calculation Results are Valid if Sync Frame is Duplicated)

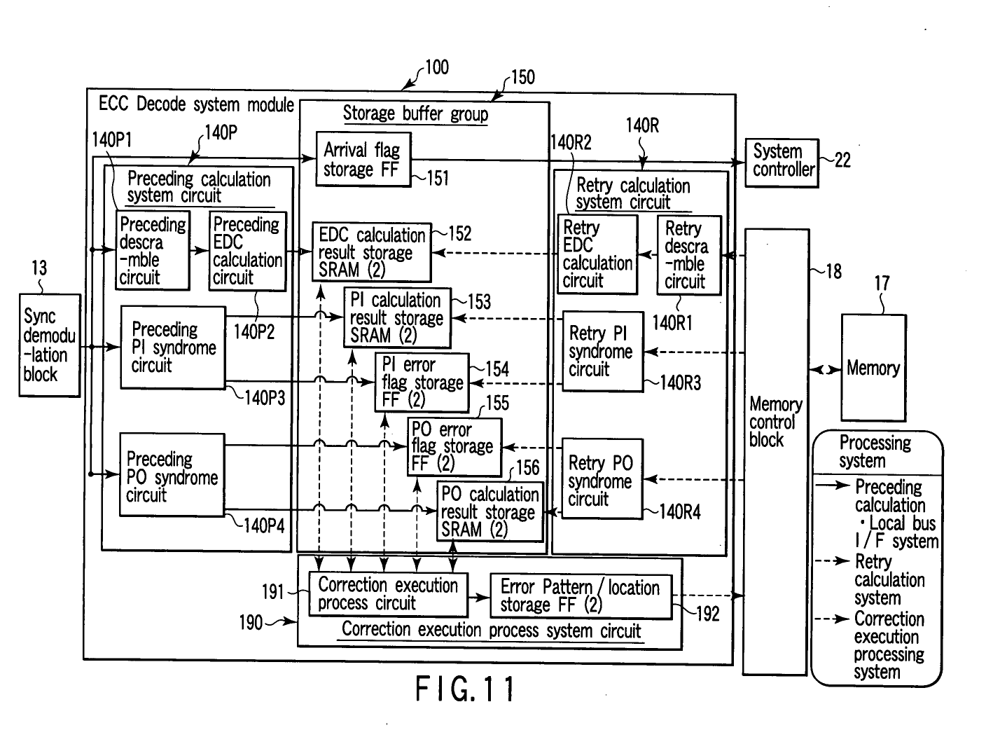

This mode is used when an error rate is emphasized. When a sync frame is duplicated, the latter (second arrived sync frame) is overwritten (in preference to the first arrived sync frame). If sync frame duplication has occurred, hardware (corresponding to arrival history information block 16 in FIG. 3; arrival flag storage FF 151 in FIG. 11 to be described later) in ECC decode system module 100 notifies system controller 22 of it. However, although the overwrite process is permitted, preceding syndrome results are preferably used for high-speed processes. Hence, if no notification is made, it is determined that preceding syndrome calculations have succeeded, and the preceding calculation results are validated. On the other hand, if notification is made, retry syndrome calculations start, and memory (DRAM) 17 overwrites data of the latter (second arrived sync frame) on that of the former (first arrived sync frame) to attain matching.

FIG. 7 shows the flow of information when sync frame duplication in the “overwrite permission mode” by <1> to <4>. More specifically, data which is A/D-converted in read channel 11 is input to sync demodulation block 13. Sync demodulation block 13 generates various attribute signals based on the input data, and outputs the generated attribute signals together with the input data. These attribute signals include an ECCOVW signal used to identify the “first-come-first-served basis mode” and “overwrite permission mode”.

Data output from sync demodulation block 13 is sent to memory (DRAM or the like) 17 via preceding calculation system circuit 140P and memory control block 18 (path<1>). Preceding calculation system circuit 140P executes processes such as syndrome calculations and the like on the basis of incoming data. During these processes, data from sync demodulation block 13 is stored in DRAM 17. If hardware detects sync frame duplication during this data transfer, if an ECCOVW signal is enabled (e.g., ECCOVW=1, i.e., “overwrite permission mode”), DRAM 17 stores data from sync demodulation block 13 to overwrite old data.

If sync frame duplication has occurred in the overwrite permission mode, the calculations made by preceding calculation system circuit 140P are invalidated, and retry calculation system circuit 140R makes new syndrome calculations using data on DRAM 17 (path<2>). The calculation results are stored in storage buffer group 150 to update data. After that, correction execution process system circuit 190 executes a correction execution process using the updated data (path<3>). Finally, data after the correction process is output to the host side via descrambler circuit 20 and interface 21 (path<4>).

When the arrangement of FIG. 7 is applied to a disc drive device of optical disc 1, this device can comprise a motor (2) which rotates a disc (1) on which sync frame data are recorded, a demodulation circuit system (3, 4, 11, 13) which demodulates information including the sync frame data from the disc (1) rotated by the motor, a memory unit (17, 18) which stores information demodulated by the demodulation circuit system (13), a preceding calculation system circuit (140P) which makes syndrome calculations based on information demodulated by the demodulation circuit system (13), a retry calculation system circuit (140R) which makes syndrome calculations based on information stored in the memory unit (17), a buffer group (150) which stores the calculation results of the preceding calculation system circuit (140P) or those of the retry calculation system circuit (140R), and a correction execution process system circuit (190) which executes error correction for the information demodulated by the demodulation circuit system (13) on the basis of the calculation results stored in the buffer group.

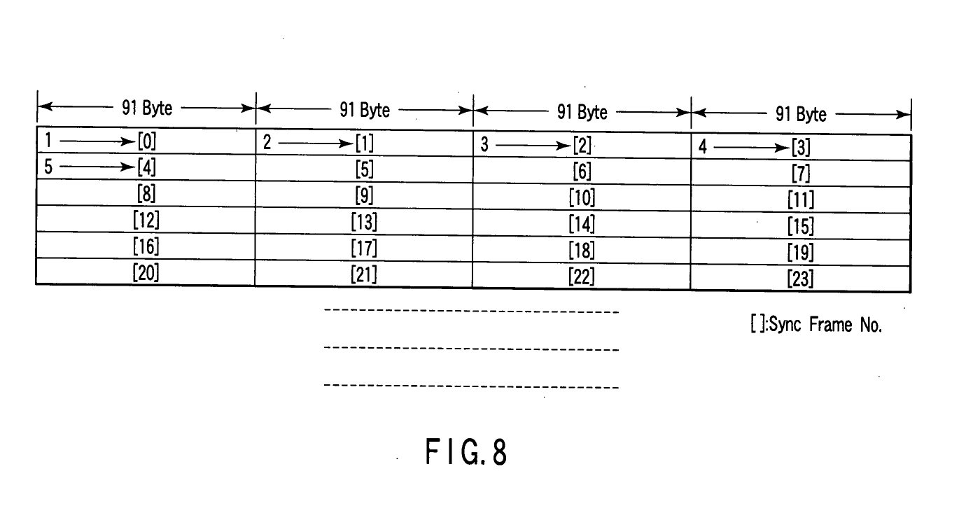

FIG. 8 is a view for explaining the concept of data transfer in the system arrangement of FIG. 7. This figure exemplifies the transfer data of sync frame data from sync demodulation block 13. In this example, one sync frame is made up of 91 bytes as in FIG. 2. In this system, if data arrival is abnormal, an abnormality is found for each sync frame (in this embodiment, such abnormality is generally called sync abnormality).

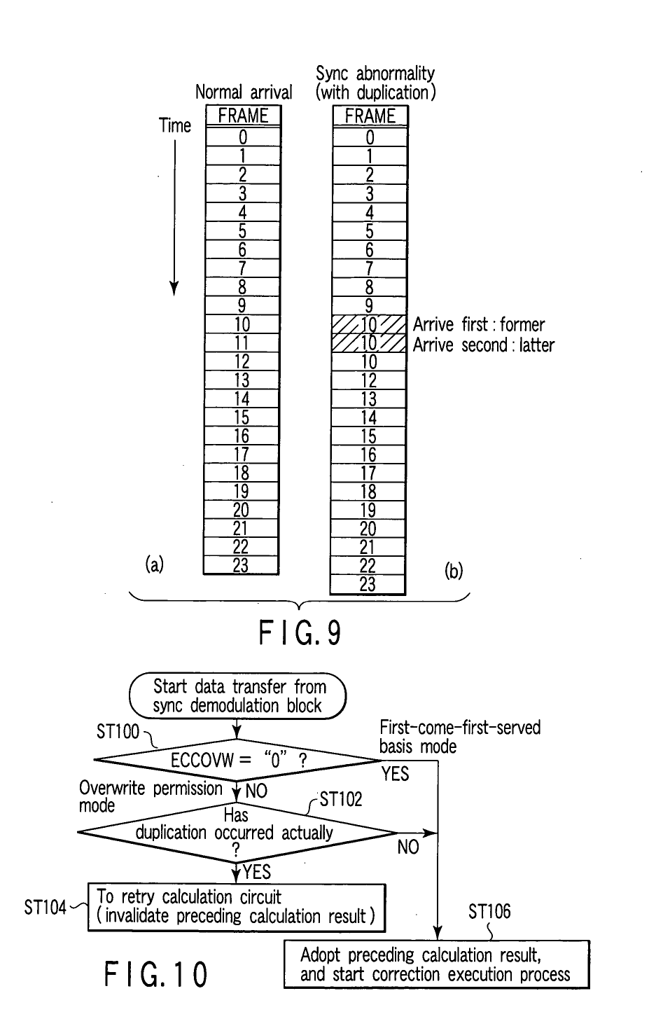

FIG. 9 is a view for explaining a case wherein sync frame data arrive normally and a case wherein sync frame data arrive redundantly (sync abnormality) in the system arrangement shown in FIG. 7. When sync frame data shown in FIG. 8 are normally sent to ECC decode system module 100 in FIG. 7, sync frames are free from duplication, as shown in FIG. 9(a). However, if sync frame duplication has occurred for any cause, sync frames arrive, as shown in FIG. 9(b) (in this example, a sync frame of frame No. 10 is duplicated). In the embodiment of the present invention, when sync frame duplication has occurred, as shown in FIG. 9(b), the handling method of the first arrived sync frame (former) and the second arrived sync frame (latter) can be appropriately changed in accordance with the operation mode (aforementioned “first-come-first-served basis mode” and “overwrite permission mode”).

FIG. 10 is a flowchart for explaining a processing example in the system arrangement of FIG. 7 (this process can be executed by firmware installed in system controller 22 in FIG. 7). This processing example pertains to mode switching based on the aforementioned ECCOVW signal. That is, if ECCOVW signal=0 (YES in step ST100), it is determined that “first-come-first-served basis mode” suited to higher multiple-speed playback is selected, and the correction execution process is done using the calculation results of preceding calculation system circuit 140P (step ST106). If “first-come-first-served basis mode” is not selected (NO in step ST100), if no sync abnormality shown in FIG. 9(b) is found (no sync frame duplication occurs) (NO in step ST102), the correction execution process is done using the calculation results of preceding calculation system circuit 140P (step ST106).

On the other hand, if sync abnormality shown in FIG. 9(b) has occurred (YES in step ST102) not in “first-come-first-served basis mode” but in “overwrite permission mode” (NO in step ST100), the second arrived sync frame is used based on the empirical rule indicating that the second arrived sync frame [10] has higher reliability (lower error probability) than the first arrived sync frame [10], and the correction execution process is done using the calculation results of retry calculation system circuit 140R (step ST104). (Summary of FIG. 10)

<Overwrite Permission Mode and First-Come-First-Served Basis Mode>

When sync frame data duplication has occurred (FIG. 9(b)), the preceding calculation result valid mode (first-come-first-served basis mode: ECCOVW=0) that gives priority to first arrived duplicated sync frame data, and the retry calculation result valid mode (overwrite permission mode: ECCOVW=1) that gives priority to second arrived duplicated sync frame data are set. In the preceding calculation result valid mode (first-come-first-served basis mode: ECCOVW=0), correction execution process system circuit 190 uses the calculation results of preceding calculation system circuit 140P (step ST106). In the retry calculation result valid mode (overwrite permission mode: ECCOVW=1), correction execution process system circuit 190 uses the calculation results of retry calculation system circuit 140R (step ST104).

<Use Retry Calculation Results in ECC if Duplication has Occurred>

It is inspected if sync frame data duplication has occurred. If duplication is found (YES in step ST102), correction execution process system circuit 190 uses the calculation results of retry calculation system circuit 140R in place of those of preceding calculation system circuit 140P.

<Use Preceding Calculation Results in ECC if No Duplication Occurs>

If no sync frame data duplication occurs (NO in step ST102), system controller 22 controls correction execution process system circuit 190 to use the calculation results of preceding calculation system circuit 140P.

FIG. 11 is a block diagram showing an example of details of ECC decode system module (LSI or the like) 100 in the system arrangement of FIG. 7. A circuit integrated in this module 100 includes five different storage buffers (152 to 156). The functions of these buffers can be roughly categorized into three functions: a preceding calculation system (140P), retry calculation system (140R), and decode process system (190).

Preceding calculation system circuit 140P performs preceding PI and PI syndrome calculations (140P3, 140P4), confirmation of PI and PO error flags, and preceding EDC calculations (140P1, 140P2). These calculation results are stored in respective storage buffers (syndrome calculation results are stored in SRAMs 153 and 156; error flags are stored in flip-flops FF 154 and 155; and EDC calculation results are stored in SRAM 152). Arrival of data transferred from sync demodulation block 13 is confirmed, and the confirmation result is stored in arrival flag storage FF 151. The flag stored in FF 151 is transferred to system controller 22. With this flag, system controller 22 can detect that data from sync demodulation block 13 reach decode system module 100. Note that each of SRAMs 153 and 156 in storage buffer group 150 has two ports to simultaneously handle read and write.

Retry calculation circuit system 140R is a path for making syndrome and EDC calculations again due to failure of the preceding calculation system. Input data of retry calculations use data which is directly written in memory (DRAM or the like) 17 from sync demodulation block 13. As in the preceding calculation system (140P), respective calculation results are stored in the storage buffers (152 to 156).

After syndrome, EDC and error flag calculation results are stored in the five storage buffers (152 to 156), correction execution process circuit 191 in correction execution process system circuit 190 executes a correction process (decode system process) using these storage data, and the processing result is stored in error pattern/error location storage buffer 192. As a result, only error pattern and error location data are transferred to memory control block 18. In DRAM 17, a correction process is applied to data which have already been held and include errors, using the correction information (error pattern and error location), thus completing error correction.

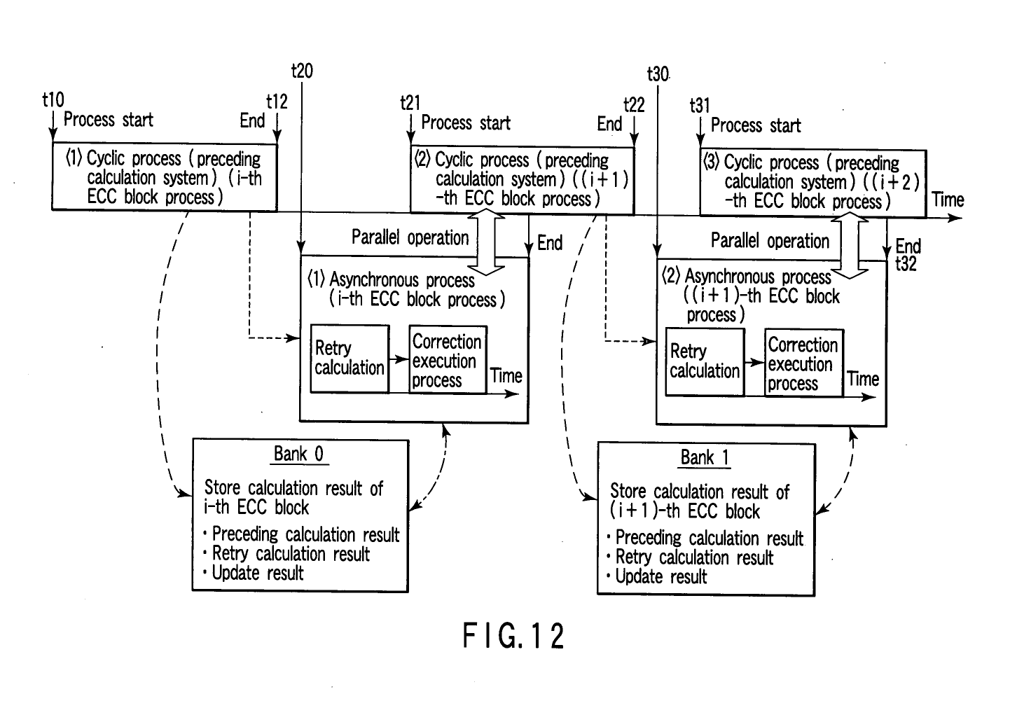

Note that numerals in parentheses such as SRAM(2), FF(2), and the like in the intra-block descriptions of buffers 152 to 156 in FIG. 11 indicate the number of banks of the corresponding buffer. The reason why a plurality of banks are used will be explained in a description of FIG. 12 below.

FIG. 12 is a diagram for explaining the concept of the operation of ECC decode system module 100 in the system arrangement shown in FIG. 7 (the process in FIG. 12 can be executed by firmware installed in system controller 22 in FIG. 7). The processing timings of the aforementioned three functions (preceding calculation system function, retry calculation system function, and correction execution process system function) will be described below with reference to FIG. 12. As described above, the functions include the preceding calculation system, retry calculation system, and correction execution process system. The preceding calculation system (140P) is cyclically processed in the order of data transferred from sync demodulation block 13.

By contrast, the retry calculation system (140R) and correction execution process system (190) are asynchronously implemented in view of processing units since they are controlled at requested start and end timings. Therefore, these two processes may operate parallelly. If these processes occur at the same time, it is difficult for one buffer to store the results of the cyclic process and asynchronous process. Hence, each of five storage buffers (see 152 to 156 in FIG. 11) has a plurality of banks.

An operation example using storage buffer group 150 in FIG. 11 having the plurality of banks, as described above, will be explained below. That is, at the end time of preceding calculations of the i-th ECC block (time t12), calculation results are stored in bank 0. After that, upon reception of a process start request of an asynchronous process (retry calculation system and correction execution process system), that process starts (time t20). As a result of retry calculations, the syndrome calculation results in bank 0 are updated. Furthermore, as a result of the correction execution process, since error pattern/error location data are obtained, the syndrome results in bank 0 are updated, thus preventing any wasteful correction process in the subsequent correction execution process.

As for this asynchronous process, if a plurality of processes (retry calculation system and correction execution process system), as shown in FIG. 12, they are processed time-serially (from time t20). At the same time, the preceding calculation system starts calculations of the (i+1)-th ECC block (time t21), and stores the calculation results in bank 1 (time t22). In this manner, the process for the i-th ECC block is performed for bank 0, and that for the (i+1)-th ECC block is performed for bank 1. Also, the (i+2)-th preceding calculation results are stored in bank 0 again. Therefore, bank switching control and initialization control of respective circuits upon bank switching become important processes. The “bank switching control and initialization control of respective circuits upon bank switching” can be implemented by firmware in system controller 22 shown in FIGS. 7, 11, and the like.

According to the aforementioned embodiment,

In a normal operation with a lower error rate (free from any sync abnormality), access to memory (DRAM) 17 is minimized using preceding calculation system circuit 140P, while when an error rate is high (sync abnormality has occurred), highly reliable retry calculation system circuit 140R can be used.

Even when sync frame duplication as sync abnormality has occurred, since a correction process can be executed using the second arrived sync frame data, the correction efficiency can be improved. Since retry calculations are made while effecting preceding calculations, the processing can be made without any processing speed drop.

### Summary of Embodiment

(1) A data processing apparatus according to an embodiment of the present invention comprises a syndrome calculation means (syndrome calculation circuit 14 in FIG. 3; preceding calculation system circuit 140P and retry calculation system circuit 140R in FIG. 7) which calculates syndromes of a demodulation data sequence (91+91 bytes). In order to realize syndrome calculations of demodulated data (91 bytes) for each sync frame obtained by excluding a sync code from one sync frame, this syndrome calculation means can include a circuit arrangement which performs these calculations (×α⁹¹, ×α2×91, . . . ).

(2) The data processing apparatus according to an embodiment of the present invention comprises ECC decode system module 100 which incorporates preceding calculation system circuit 140P and retry calculation system circuit 140R. When sync frame data duplication has occurred, this module 100 can execute processes without ignoring second arrived data, thus improving the correction efficiency.

(3) Furthermore, ECC decode system module 100 includes a plurality of systems of storage buffer groups (in FIG. 11, the PI system includes two systems 153 and 154, and the PO system includes two systems 155 and 156). With this arrangement, since the retry calculations and correction execution process can be done parallel to the preceding calculation process, a correction process with high efficiency can be achieved without any processing speed drop.

(4) Moreover, a plurality of circuits (preceding calculation system circuit and retry calculation system circuit) can be selectively used in correspondence with the playback speed.

(5) In addition, the plurality of circuits can be selectively used in accordance with an error counter (e.g., one frame loss in step S2 in FIG. 6 is detected as error occurrence of 91 bytes, and a count value of that error occurrence).

(6) Also, the plurality of circuits can be selectively used while monitoring power consumption. (More specifically, in a battery-driven portable device or the like, the preceding calculation system circuit is used in a long life mode which is used to prolong the battery life, and energization to the retry calculation system circuit system circuit is cut).

Note that the present invention is not limited to the aforementioned embodiments, and various modifications may be made on the basis of techniques available at that time without departing from the scope of the invention when it is practiced at present or in the future. The respective embodiments may be combined as needed as long as possible, and combined effects can be obtained in such case. Furthermore, the embodiments include inventions of various stages, and various inventions can be extracted by appropriately combining a plurality of required constituent elements disclosed in this application. For example, even when some required constituent elements are deleted from all the required constituent elements disclosed in the embodiments, an arrangement from which those required constituent elements are deleted can be extracted as an invention.

What is claimed is:

1. A data processing apparatus comprising:
a memory unit configured to store information including sync frame data;
a preceding calculation system circuit configured to make a syndrome calculation from the information including sync frame data;
a retry calculation system circuit configured to make a syndrome calculation from information stored in the memory unit;
a buffer group configured to store a calculation result of the preceding calculation system circuit or a calculation result of the retry calculation system circuit; and
a correction execution process system circuit configured to execute error correction for the information including sync frame data according to the calculation result stored in the buffer group.

2. A disc drive device comprising:
a motor configured to rotate a disc on which sync frame data is recorded;
a demodulation circuit system configured to demodulate information including the sync frame data from the disc rotated by the motor;
a memory unit configured to store the information demodulated by the demodulation circuit system;
a preceding calculation system circuit configured to make a syndrome calculation from the information demodulated by the demodulation circuit system;
a retry calculation system circuit configured to make a syndrome calculation from information stored in the memory unit;
a buffer group configured to store a calculation result of the preceding calculation system circuit or a calculation result of the retry calculation system circuit; and
a correction execution process system circuit configured to execute error correction for the information demodulated by the demodulation circuit system according to the calculation result stored in the buffer group.

3. A device according to claim 1, wherein information which is to undergo calculations of the preceding calculation system circuit and the retry calculation system circuit is information corresponding to an ECC block including PI and PO parity data,
the preceding calculation system circuit includes a syndrome calculation circuit corresponding to the PI parity data and a syndrome calculation circuit corresponding to the PO parity data,
the retry calculation system circuit includes a syndrome calculation circuit corresponding to the PI parity data and a syndrome calculation circuit corresponding to the PO parity data, and
the buffer group includes a PI buffer configured to store a syndrome calculation result of the information corresponding to the PI parity data, and a PO buffer configured to store a syndrome calculation result of the information corresponding to the PO parity data.

4. A device according to claim 1, further comprising a system controller configured to parallel execute a process upon making the calculation of the retry calculation system circuit for an i-th ECC block and another process upon making the calculation of the preceding calculation system circuit for an (i+1)-th ECC block, where i is an integer number.

5. A device according to claim 1, further comprising a system controller in which when the sync frame data has been duplicated, a preceding calculation result valid mode that gives priority to first arrived duplicated sync frame data, and a retry calculation result valid mode that gives priority to second arrived duplicated sync frame data are set, wherein
the correction execution process system circuit uses the calculation result of the preceding calculation system circuit in the preceding calculation result valid mode, and
the correction execution process system circuit uses the calculation result of the retry calculation system circuit in the retry calculation result valid mode.

6. A device according to claim 1, further comprising a system controller configured to inspect whether the sync frame data has been duplicated, and control the correction execution process system circuit to use the calculation result of the retry calculation system circuit in place of the calculation result of the preceding calculation system circuit if duplication is found.

7. A device according to claim 6, wherein the system controller is configured to control the correction execution process system circuit to use the calculation result of the preceding calculation system circuit if no duplication is found.

8. A data processing method of performing an ECC process using information of sync frames that arrive successively, comprising:
executing, if the information of the sync frames does not suffer any duplication, the ECC process using the sync frame information in an arrival order; and
executing, if the information of the sync frames suffers duplication, the ECC process using a second arrived sync frame of the information of duplicated sync frames.

9. A method according to claim 8, wherein the information of the sync frames can undergo syndrome calculation processes by a preceding calculation system and a retry calculation system, and the syndrome calculation process of the preceding calculation system and the syndrome calculation process of the retry calculation system undergo a parallel process at least partially.

10. A device according to claim 2, wherein information which is to undergo calculations of the preceding calculation system circuit and the retry calculation system circuit is information corresponding to an ECC block including PI and PO parity data,
the preceding calculation system circuit includes a syndrome calculation circuit corresponding to the PI parity data and a syndrome calculation circuit corresponding to the PO parity data,
the retry calculation system circuit includes a syndrome calculation circuit corresponding to the PI parity data and a syndrome calculation circuit corresponding to the PO parity data, and
the buffer group includes a PI buffer configured to store a syndrome calculation result of the information corresponding to the PI parity data, and a PO buffer configured to store a syndrome calculation result of the information corresponding to the PO parity data.

11. A device according to claim 2, further comprising a system controller configured to parallel execute a process upon making the calculation of the retry calculation system circuit for an i-th ECC block and another process upon making the calculation of the preceding calculation system circuit for an (i+1)-th ECC block, where i is an integer number.

12. A device according to claim 2, further comprising a system controller in which when the sync frame data has been duplicated, a preceding calculation result valid mode that gives priority to first arrived duplicated sync frame data, and a retry calculation result valid mode that gives priority to second arrived duplicated sync frame data are set, wherein
the correction execution process system circuit uses the calculation result of the preceding calculation system circuit in the preceding calculation result valid mode, and
the correction execution process system circuit uses the calculation result of the retry calculation system circuit in the retry calculation result valid mode.

13. A device according to claim 2, further comprising a system controller configured to inspect whether the sync frame data has been duplicated, and control the correction execution process system circuit to use the calculation result of the retry calculation system circuit in place of the calculation result of the preceding calculation system circuit if duplication is found.

14. A device according to claim 13, wherein the system controller is configured to control the correction execution process system circuit to use the calculation result of the preceding calculation system circuit if no duplication is found.
